(19) United States
(12) Patent Application Publication
(10) Pub. No.: US 2025/0208184 A1
(43) Pub. Date: Jun. 26, 2025

(54) PUSHER FOR USE IN AN AUTOMATED TEST EQUIPMENT, A TEST ARRANGEMENT COMPRISING THE PUSHER AND A METHOD FOR MECHANICALLY PUSHING THE DEVICE UNDER TEST WITH AN ANTENNA INTO A DEVICE UNDER TEST SOCKET

(71) Applicant: Advantest Corporation, Tokyo (JP)

(72) Inventors: Jan HESSELBARTH, Stuttgart (DE); José MOREIRA, Stuttgart (DE)

(21) Appl. No.: 19/078,442

(22) Filed: Mar. 13, 2025

Related U.S. Application Data
(63) Continuation of application No. PCT/EP2022/075586, filed on Sep. 14, 2022.

(51) Int. Cl. G01R 29/08

(52) U.S. Cl. CPC G01R 29/0871; G01R 29/0892

(57) ABSTRACT

An embodiment according to the invention comprises a pusher for use in an automated test equipment to mechanically push a device under test, DUT, comprising an antenna or an antenna array into a DUT socket. The pusher comprise relatively higher permittivity dielectric regions and relatively lower permittivity dielectric regions. The relatively higher permittivity dielectric regions and the relatively lower permittivity dielectric regions are forming a structure of higher permittivity dielectric predominantly parallel columns, e.g., rods or pillars or poles, with lower permittivity dielectric regions between these columns. Alternatively, the relatively higher permittivity dielectric regions and the relatively lower permittivity dielectric regions are forming a structure of a higher permittivity dielectric block with lower permittivity dielectric predominantly parallel filled or unfilled holes. The higher permittivity dielectric columns or the lower permittivity dielectric holes extend in a first direction, which is within ±45° of a pushing direction.

### CROSS-REFERENCES TO RELATED APPLICATIONS

This application is a continuation of copending International Application No. PCT/EP2022/075586, filed Sep. 14, 2022, which is incorporated herein by reference in its entirety.

Embodiments according to the present invention relate to a pusher configured to push a device under test (DUT) into a device under test socket. Further embodiments relate to a test arrangement comprising a device under test to be pushed into a device under test socket (DUT-socket) by a pusher. Further embodiments according to the invention relate to a concept and/or design of a high-transparency pusher for planar antenna modules. Embodiments according to the present invention relate to a high-transparency pusher for over-the-air test-sockets.

### BACKGROUND OF THE INVENTION

Millimeter-wave transceiver modules often comprise electronics and planar antennas in a device of or with a small form factor. The size of the module is often determined by the antenna aperture area or by the antenna array aperture area. Such a module is usually preferred (sometimes required) to be over-the-air (OTA) tested in an automated test equipment (ATE) at or in production environment. Handling and/or testing the modules may require pushing the module mechanically into a DUT-socket by a pushing means or pusher on or onto the side of the antenna or antenna array aperture.

The device under test (DUT) antenna or antenna array is designed to have air and/or a (very) thin dielectric material layer on top of it so it does not disturb the DUT antenna or antenna array. For testing the DUT in an ATE or for ATE testing these conditions are mimicked or simulated partially by the pusher. The pusher, which can be part of an OTA socket and/or of a handler arm of an ATE or of an ATE test cell might be a critical part in an OTA testing, because it touches the antenna or antenna array in or of the DUT while pushing it down into a DUT-socket.

The problem of or with designing a pusher for an OTA test-socket is the material of the pusher. The material of the pusher is preferred to have a (very) low dielectric constant, which is close to the dielectric constant of air, or more broadly, the electric properties of the pusher-material is preferred to be close to the electric properties of air. Also, the pusher-material is preferred to be mechanically strong to support the mechanical stress of multiple cycles of pushing the DUT into the DUT-socket. In other words, the pusher is preferred to be electromagnetically transparent, or nearly transparent, so as to avoid disturbing the antennas of the DUT, while being mechanically solid and stiff. Unfortunately, due to physical reasons, there is no material available that has both of these properties.

Dielectric materials with (very) low relative permittivity are known to fulfil the need of electromagnetic transparency, but at the same, these materials are mechanically soft. On the contrary, a mechanically stiff pusher is made of a high permittivity material, which can cause a de-tuning of the antenna feed impedance and/or can change the antenna radiation pattern.

### SUMMARY

An embodiment may have a pusher for use in an automated test equipment to mechanically push a device under test into a device under test socket, wherein the pusher comprises higher permittivity dielectric regions and lower permittivity dielectric regions forming a structure of higher permittivity dielectric columns with lower permittivity dielectric regions between the columns or a structure of a higher permittivity dielectric block with lower permittivity dielectric holes, wherein the higher permittivity dielectric columns or the holes extend in a first direction, which is within +/−45° of a pushing direction.

Another embodiment may have a test arrangement for testing a device under test, comprising the device under test with an antenna pushed into a device under test socket by a pusher according to the invention in order to test the device under test.

Another embodiment may have a method for mechanically pushing a device under test into a device under test socket of an automated test equipment, wherein the method comprises mechanically pushing the device under test into the device under test socket with a pusher, which comprises a structure of higher permittivity dielectric columns with lower permittivity dielectric regions between the columns or a structure of a higher permittivity dielectric block with lower permittivity dielectric holes, wherein the higher permittivity dielectric columns or the lower permittivity dielectric holes are extending in a first direction, which is within +/−45° of a pushing direction.

An embodiment according to the invention comprises a pusher for use in an automated test equipment (ATE) to mechanically push a device under test (DUT) comprising an antenna or an antenna array into a DUT socket. The pusher comprises relatively higher permittivity dielectric regions and relatively lower permittivity dielectric regions. The relatively higher permittivity dielectric regions and the relatively lower permittivity dielectric regions are forming a structure of higher permittivity dielectric predominantly parallel columns, e.g., rods or pillars or poles, with lower permittivity dielectric regions between these columns. Alternatively, the relatively higher permittivity dielectric regions and the relatively lower permittivity dielectric regions are forming a structure of a higher permittivity dielectric block with lower permittivity dielectric predominantly parallel filled or unfilled holes. The higher permittivity dielectric columns or the lower permittivity dielectric holes extend in a first direction, which is within ±45° of a pushing direction.

To address the challenge of having a mechanically stiff but electromagnetically transparent or nearly transparent, pusher, the embodiment of the pusher or the structure of the pusher has a hybrid design in which mechanically soft materials with low dielectric constant and mechanically strong materials with high dielectric constant are comprised or mixed. A pusher with this hybrid design can be applied to push DUTs with single or dual-polarized antennas as well.

In other words, the design of the pusher and dimensions of the high permittivity dielectric regions and/or of the low permittivity dielectric regions of the pusher might be important or critical for the pusher in order to avoid an impact (or an excessive impact) on the electromagnetic waves received or transmitted by the DUT antenna or DUT antenna array. The high permittivity dielectric regions are improving the mechanical stiffness of the pusher, while the low permittivity dielectric regions are improving the electromagnetic transparency of the pusher.

Also, the fact that the higher permittivity dielectric columns or the higher permittivity dielectric material around the lower permittivity dielectric holes extend in a direction, which is within ±45° parallel to the pushing direction also improves the stability, the durability and the mechanical stiffness of the pusher.

In an embodiment, the higher permittivity dielectric columns or the lower permittivity dielectric holes are circular or square-shaped or triangle-shaped or cross-shaped.

The shape of the higher permittivity dielectric columns or the lower permittivity dielectric holes can be chosen from basic geometric shapes in order to meet diverse potential goals. Such goals might be for example, maximizing the electromagnetic transparency or the mechanical stiffness of the pusher; keeping a fix ratio between the higher permittivity and the lower permittivity dielectric materials; achieving a pusher structure matching to the profile of the DUT; or improve the mechanical stability of the pusher.

In an embodiment, the structure comprises between 5 and 50, or preferably between 10 and 30 higher permittivity dielectric columns or lower permittivity dielectric holes per free space wavelength of an electromagnetic wave transmitted or received by an antenna or an antenna array of a DUT, e.g., as a center frequency of an operation frequency band of the device under test.

The main requirements against the pusher are a mechanical stiffness and an electromagnetic transparency. The number of higher permittivity dielectric columns or lower permittivity dielectric holes are chosen so that the pusher may remain transparent, or nearly transparent, for the electromagnetic waves transmitted or received by the antenna or the antenna array of the DUT while remaining mechanically stiff to be used to push a DUT into a DUT-socket. Based on previous conducted experiments between 5 and 50 or preferably between 10 and 30 higher permittivity dielectric columns or lower permittivity dielectric holes per free space wavelength are fulfilling this requirement.

The minimum number of the columns, e.g. 5 or preferably 10, is a number by which the pusher remains mechanically stable and stiff, while the maximum number of columns, e.g. 50 or preferably 30, is a number by which the pusher still remains electromagnetically transparent, or nearly transparent, at least for the electromagnetic waves transmitted or received by the antenna or the antenna array of the DUT.

The maximum number of the holes, e.g. 50 or preferably 30, is a number by which the pusher remains mechanically stable and stiff, while the minimum number of holes, e.g. 5 or preferably 10, is a number by which the pusher still remains electromagnetically transparent, or nearly transparent, at least for the electromagnetic waves transmitted or received by the antenna or the antenna array of the DUT.

In an embodiment, the structure comprises a matrix of higher permittivity dielectric columns or of lower permittivity dielectric holes or a regular grid, e.g., rectangular grid or triangular grid of higher permittivity dielectric columns or of lower permittivity dielectric holes.

Instead of locally adapting the structure of each and every pusher to the radiating slots or edges of a dual-polarized antenna surface of a DUT, periodical structures of higher permittivity dielectric columns or lower permittivity dielectric holes might be used. Thus, the same pusher might be used for different DUTs or for different antennas of the same DUTs.

The pusher-structure with a regular grid of higher permittivity dielectric columns or lower permittivity dielectric holes is semi-isotropic in the x-y plane for an operation in or with both orthogonal polarizations. Potential structures (or choices) covering the x-y plane are, for example, i) a square grid with square-cross-section air-filled cylinders, ii) a triangular grid with circular-cross-section air-filled cylinders, and iii) a triangle grid with triangular-cross-section air-filled cylinders.

According to embodiments, the structure, e.g. the regions of higher permittivity and lower permittivity dielectric materials comprising columns or holes, comprises between 9 and 66.6 vol. % or between 20 and 60 vol. % relatively higher permittivity dielectric regions and between 91 and 33.3 vol. % or between 80 and 40 vol. % relatively lower permittivity dielectric regions. Preferably, the structure comprises between 30 and 50 vol. % relatively higher permittivity dielectric regions and between 70 and 50 vol. % relatively lower permittivity dielectric regions.

A well-chosen ratio between the relatively higher permittivity dielectric regions and the relatively lower permittivity dielectric regions results in a pusher, which remains transparent, or nearly transparent, for the electromagnetic waves transmitted or received by the antenna or the antenna array of the DUT, while remaining mechanically stiff to be used to push a DUT into a DUT-socket.

In an embodiment, the surface of the pusher, which is configured to touch the device under test, is formed or configured or machined, so that the pusher avoids touching or approaching close-by, e.g. within a distance of 1/10 of a wavelength of an electromagnetic wave transmitted or received by an antenna of the DUT, a conductive edge of the antenna of the DUT. The conductive edge might be a metallic edge of the antenna structure, which contributes strongly to the radiation.

Touching or approaching close-by the DUT-antenna by the pusher affects negatively a performance of the antenna of the DUT. Dielectric loading of the radiating edges of DUT-antennas or their close proximity affect their resonance. Changing the resonance changes the feed impedance and the radiation behavior of the antenna. Moreover, if the pusher is large compared to the wavelength and has a not-small permittivity, it is preferred to avoid arbitrary resonances within the pusher itself, which would lead to changes (sometimes disastrous changes) of radiation and feed characteristics.

In an embodiment, the pusher comprises a spacer configured to be in between the structure and the DUT. The spacer is perpendicular, within a tolerance of +/−15° to the columns or holes and/or the spacer is parallel, within a tolerance of +/−15°, to a surface of the DUT to be pushed by the pusher.

Benefits of the spacer is the exchangeability, so in any case, not the whole pusher has to be replaced, just the spacer. Also, if the pusher has to be adapted to a new DUT or in case of breakage, only the spacer is replaced, which saves costs and material.

In an embodiment, the spacer is a structured spacer, that is, it is further formed or configured or machined to touch the device under test, so that the spacer avoids touching or approaching close-by, e.g. within a distance of 1/10 of a wavelength of an electromagnetic wave transmitted or received by an antenna of the DUT, a conductive edge of the antenna of the DUT. The conductive edge might be a metallic edge of the antenna structure, which contributes strongly to the radiation.

As the spacer is exchangeable, each kind of antenna design could have a dedicated spacer, which avoids touching or approaching close-by the conductive edges of the antenna or antenna array of the DUT. That is, the same pusher could be applied with different spacers for different DUTs, making the pusher and thus the ATE more flexible.

In an embodiment, the spacer has a relative permittivity less than or equal to 1.5.

The spacer which is configured to be in closed contact with the DUT-antenna without touching or approaching close-by the conductive edges of the antenna is made of a low relative permittivity dielectric material in order to be transparent, or nearly transparent, for the electromagnetic waves received or transmitted by the antenna of the DUT.

In an embodiment, the spacer has a thickness of between 50 micrometers and 500 micrometers.

The spacer is configured to cover the whole surface area of the antenna of the DUT. The above mentioned thickness of between 50 and 500 micrometers helps to reach this even if the surface area of the antenna is uneven. Also, good mechanical stability can be achieved without excessively degrading antenna capabilities.

In an embodiment, the spacer has a thickness of between 100 micrometers and 200 micrometers.

If the antenna area of the DUT is slightly (or sufficiently) even, a thickness of between 100 micrometers and 200 micrometers might be also enough to cover the whole surface area of the antenna of the DUT.

In an embodiment, the pusher comprises a dielectric slab, e.g. a dielectric slab made of a mechanically stiff material with a relatively higher permittivity, which is transversal to or perpendicular, within a tolerance of +/−15°, to the pushing direction. The dielectric slab is configured to mechanically support and/or stabilize at least the higher permittivity dielectric columns or at least the higher permittivity dielectric block around the lower permittivity dielectric holes.

The mechanically stronger dielectric slab is transversal to the pushing direction and attached to the higher permittivity dielectric columns or to the higher permittivity dielectric block. This makes the pusher more durable, stiffer and more stable, as for example, it prevents independent movements of single higher permittivity dielectric columns of the pusher, if for example the surface of the DUT is uneven.

In an embodiment, the dielectric slab has a thickness, which equals, within a tolerance of 1/10 a wavelength of an electromagnetic wave transmitted or received by an antenna of the DUT, e.g., at a center frequency of an operation frequency band of the DUT, to an integer multiple of a half wavelength of an electromagnetic wave in the dielectric material of the dielectric slab, which calculates to the free space wavelength divided by the square-root of the relative permittivity of the dielectric, transmitted or received by the antenna of the DUT, e.g., at a center frequency of an operation frequency band of the DUT. The distance between the dielectric slab and the surface of the antenna of the device under test is at least one wavelength of the electromagnetic wave transmitted or received by the antenna of the DUT, e.g., at the center frequency band of an operation frequency band of the DUT.

The dielectric slab is made of a mechanically strong material, which has a relatively high permittivity. The dielectric slab is preferred to be electromagnetically as transparent as possible. Thus, the thickness of the slab and/or the distance between the DUT-antenna and the slab is chosen in a way, that the negative effect of the slab on the electromagnetic waves transmitted or received by the antenna of the DUT is minimal, e.g. the loss of electromagnetic wave transmitted or received by the antenna of the DUT is minimal.

In an embodiment, a length of the higher permittivity dielectric columns or of the lower permittivity dielectric holes in the pushing direction is between 0.5 and 2 times a free space wavelength of an electromagnetic wave transmitted or received by an antenna of the DUT, e.g., at the center frequency of an operation frequency band of the DUT.

The length of the higher permittivity dielectric columns or of the lower permittivity dielectric holes, that is the length of the structure of the pusher, in the pushing direction, e.g. in the direction of the main lobe of the electromagnetic waves transmitted or received by the DUT-antenna, is defining for the amount of electromagnetic waves absorbed by the pusher. A pusher with limited length or higher permittivity dielectric columns or lower permittivity dielectric holes with limited length limits the amount of electromagnetic waves absorbed from the electromagnetic waves transmitted or received by the antenna of the DUT. Thus, with limited length of the alternating parallel layers, the pusher remains as transparent as possible to the electromagnetic wave received or transmitted by the antenna of the DUT, while remaining mechanically stiff.

In an embodiment, the relatively higher permittivity dielectric regions have a relative permittivity greater than 2 or preferably between 2.5 and 4.

The relative permittivity of mechanically strong materials is high. Materials used for providing mechanical stability and strength to the pusher are found to have a relative permittivity of at least 2. A relative permittivity between 2.5 and 4 gives a good balance between mechanical strength and electromagnetic transparency.

In an embodiment the relatively higher permittivity dielectric regions are made of polymer or of polycarbonate or of quartz or of Teflon or of PEEK material.

In an embodiment, the relatively lower permittivity dielectric regions have a relative permittivity less than or equal to 1.5.

Relatively lower permittivity materials, with a permittivity of 1.5, are transparent or near to transparent to electromagnetic waves transmitted or received by the antenna of the DUT.

In an embodiment, the relative lower permittivity dielectric regions comprise air.

Air has a low relative permittivity. So in a simple pusher design only the relatively higher permittivity dielectric regions are built and the relatively lower permittivity dielectric regions are left void, e.g. are filled with air. In this case, the air around and/or between the relatively higher permittivity dielectric columns or in the holes are part of the structure of the pusher.

In an embodiment, the pushing direction is parallel, with a tolerance of +/−15°, to a far field direction of an electrical field in a main lobe of an antenna of the DUT. Alternatively, the pushing direction is perpendicular, within a tolerance of +/−15°, to the main surface of the DUT. A further option is that the pushing direction is perpendicular, within a tolerance of +/−15° to the main surface of the DUT socket.

In order to improve the transparency of the pusher to the electromagnetic waves transmitted or received by the DUT-antenna, the effective area of the structure of the pusher, in particular the effective area of the higher permittivity dielectric regions of the pusher, is minimized. The effective area of the structure is minimal, if the direction of the structure is parallel to the main lobe of the received or transmitted electromagnetic waves, which is in most cases also perpendicular, within a tolerance of +/−15°, to the main surface of the DUT or of the DUT-socket.

A further embodiment comprises a test arrangement for testing a device under test. The test arrangement comprises the device under test with an antenna or an antenna array, an above-discussed pusher and a device under test socket. The device under test with an antenna or an antenna array of the test arrangement is configured to be pushed into the device under test socket by the discussed pusher.

Another embodiment according to the invention creates a method for mechanically pushing the device under test, comprising an antenna or an antenna array, into a device under test socket of an automated test equipment. The method comprising mechanically pushing the device under test into the device under test socket with an above-discussed pusher.

It should be noted, that methods and corresponding apparatuses are based on the same considerations. Moreover, the methods may be supplemented by any of the features or functionalities and details which are described herein with respect to the apparatuses both individually and taken in combination.

### BRIEF DESCRIPTION OF THE DRAWINGS

Embodiments of the present invention will be detailed subsequently referring to the appended drawings, in which:

FIG. 1 shows a schematic representation of an embodiment of a test arrangement comprising a DUT socket, a DUT with antennas and an embodiment of a pusher;

FIG. 2 shows a schematic representation of an embodiment of a pusher configured to repeatedly push DUTs into a DUT-socket;

FIG. 3 shows a photo of an embodiment of a test arrangement without a DUT, comprising a pusher and a DUT socket with a test antenna;

FIG. 4 shows a Dielectric constant-Strength diagram, in which abscissa-values represent dielectric constant values, and ordinate-values represent flexural strength values;

FIG. 5a shows an initial DUT patch antenna without any pusher;

FIG. 5b shows a DUT patch antenna with a conventional pusher;

FIG. 5c shows a DUT patch antenna with a higher-permittivity dielectric slab;

FIG. 5d shows a DUT patch antenna with a pusher structure, in which regions of relatively higher permittivity dielectric material are separated by air or by regions of low-permittivity dielectric material;

FIG. 5e shows a DUT patch antenna with a lower-permittivity dielectric spacer;

FIG. 6a shows a 3D simulation of a DUT with a dual-polarized patch antenna;

FIG. 6b shows simulated input reflection coefficient measurement results on a diagram and on a Smith chart;

FIG. 7a shows a 3D simulation of an arrangement comprising a patch antenna and a conventional pusher;

FIG. 7b shows simulated input reflection coefficient measurement results on a diagram and on a Smith chart and radiation pattern simulations for two exemplary, perpendicular cut-planes for one selected polarization, when the relative permittivity of the pusher is 1.0;

FIG. 7c shows simulated input reflection coefficient measurement results on a diagram and on a Smith chart and radiation pattern simulations for two exemplary, perpendicular cut-planes for one selected polarization, when the relative permittivity of the pusher is 1.2;

FIG. 7d shows simulated input reflection coefficient measurement results on a diagram and on a Smith chart and radiation pattern simulations for two exemplary, perpendicular cut-planes for one selected polarization, when the relative permittivity of the pusher is 3.6;

FIG. 8a shows a 3D simulation of an arrangement comprising a patch antenna and a spacer layer;

FIG. 8b shows simulated input reflection coefficient measurement results on a diagram and on a Smith chart, when the relative permittivity of the spacer is 1.3;

FIG. 9 shows a table comparing properties of three different potential structures of a pusher

FIG. 10a shows four simulated pusher structures to be measured;

FIG. 10b shows simulated input reflection coefficient measurement results on a diagram and on a Smith chart and radiation pattern simulations for two exemplary, perpendicular cut-planes for one selected polarization, when the pusher comprises a spacer, the first structure (44% square-grid) of FIG. 10a and a λ/2 slab with εᵣₑₗ=1.3/3.6/3.6;

FIG. 10c shows simulated input reflection coefficient measurement results on a diagram and on a Smith chart and radiation pattern simulations for two exemplary, perpendicular cut-planes for one selected polarization, when the pusher comprises a spacer, the second structure (44% triangle-hole-grid) of FIG. 10a and a λ/2 slab with εᵣₑₗ=1.3/3.6/3.6;

FIG. 10d shows simulated input reflection coefficient measurement results on a diagram and on a Smith chart and radiation pattern simulations for two exemplary, perpendicular cut-planes for one selected polarization, when the pusher comprises a spacer, the first structure (36% square-grid) of FIG. 10a and a λ/2 slab with εᵣₑₗ=1.3/3.6/3.6;

FIG. 10e shows simulated input reflection coefficient measurement results on a diagram and on a Smith chart and radiation pattern simulations for two exemplary, perpendicular cut-planes for one selected polarization, when the pusher comprises a spacer, the fourth structure (36% triangle-hole-grid) of FIG. 10a and a λ/2 slab with εᵣₑₗ=1.3/3.6/3.6; and

FIG. 11 shows a comparison table with respect to the change of feed reflection coefficient.

### DETAILED DESCRIPTION OF THE INVENTION

In the following, different inventive embodiments and aspects will be described. Also, further embodiments will be defined by the enclosed claims. It should be noted that any embodiments as defined by the claims may optionally be supplemented by any of the details, features and functionalities described herein. Also, the embodiments described herein may be used individually, and may also optionally be supplemented by any of the details, features and functionalities included in the claims.

Also, it should be noted that individual aspects described herein may be used individually or in combination. Thus, details may be added to each of said individual aspects without adding details to another one of said aspects. It should also be noted that the present disclosure describes, explicitly or implicitly, features usable in an automatic test equipment, in a test arrangement or in a pusher. Thus, any of the features described herein may be used in the context of an automatic test equipment, in the context of a test arrangement or in the context of a pusher.

Moreover, features and functionalities disclosed herein, relating to a method, may also be used in an apparatus configured to perform such functionalities. Furthermore, any features and functionalities disclosed herein with respect to an apparatus may also be used in a corresponding method. In other words, the methods disclosed herein may be supplemented by any of the features and functionalities described with respect to the apparatuses.

The present invention will be understood more fully from the detailed description given below and from the accompanying drawings of embodiments of the present invention, which, however, should not be taken to limit the present invention to the specific embodiments described, but are for explanation and understanding only.

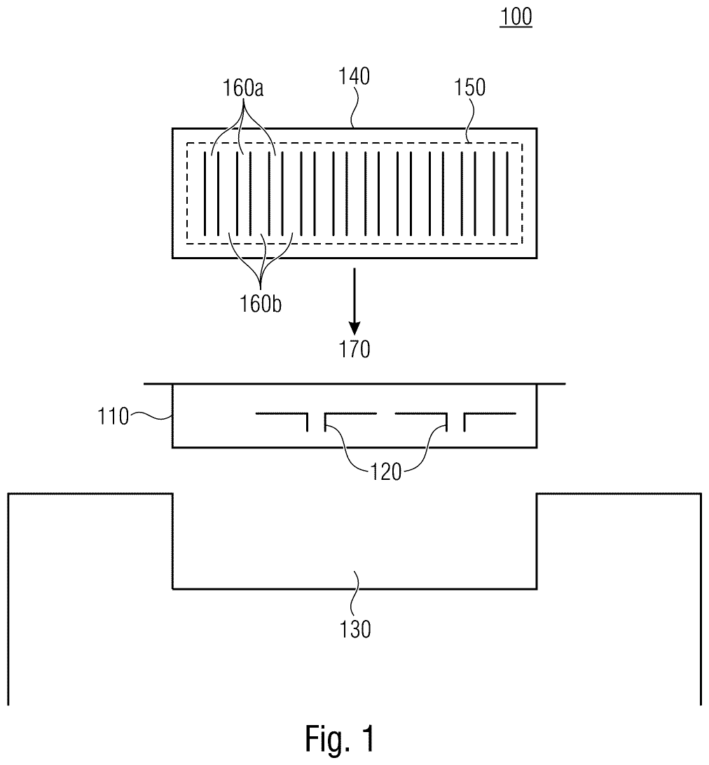

### Embodiment According to FIG. 1

FIG. 1 shows a schematic representation of an embodiment of a test arrangement 100 for testing a device under test (DUT) 110 comprising one or more antennas 120 and/or antenna arrays 120. The test arrangement 100 comprises a DUT socket 130, the DUT 110 with the antennas 120, and an embodiment of a pusher 140.

The test arrangement 100 is configured to test the DUT 110, in particularly the antennas 120 of the DUT 110. The DUT 110 is configured to be pushed in a pushing direction 170 into the device under test socket 130 by the pusher 140.

The pusher 140 is a schematic representation of an embodiment, which comprises a structure 150 comprising relatively higher permittivity dielectric regions 160a and relatively lower permittivity dielectric regions 160b, in which the meaning of “relatively” is, that the permittivity of a given dielectric region is higher or lower relative to other dielectric regions of the pusher 140. The structure 150 may comprise higher permittivity dielectric parallel columns 160a, e.g. rods or pillars or poles, or lower permittivity dielectric regions 160b between the columns 160a. Alternatively, the structure may comprise a higher permittivity dielectric block 160a with lower permittivity dielectric predominantly parallel filled or unfilled holes 160b within the higher permittivity dielectric block 160a. In either way, the higher permittivity dielectric columns 160a or the lower permittivity dielectric holes 160b extend in a direction within +/−45° of the pushing direction 170.

The pusher 140 is configured to mechanically push a device under test 110 comprising an antenna 120 or an antenna array 120 into a device under test socket 130 of an automated test equipment. The structure 150 of the pusher 140 with the relatively higher permittivity dielectric regions 160a and the relatively lower permittivity dielectric regions 160b improves significantly the transparency of the pusher 140 compared to conventional pushers for the electromagnetic waves transmitted or received by the antennas 120 of the DUT 110, while the pusher 140 remains mechanically stiff enough to repeatedly push DUTs 110 into a DUT socket 130 in a production environment.

The structure 150 comprises between 9 vol. % and 66.6 vol. % or between 20 and 60 vol. % higher permittivity dielectric regions 160a and between 91 vol. % and 33.3 vol. % or between 80 and 40 vol. % lower permittivity dielectric regions 160b. Preferably, the structure comprises between 30 and 50 vol. % higher permittivity dielectric regions 160a and between 70 and 50% lower permittivity dielectric regions 160b. For example, the higher permittivity dielectric regions 160a are columns, rods, pillars, or poles with lower permittivity dielectric regions 160b between the columns. The higher permittivity dielectric columns 160a extend within +/−45° of a pushing direction 170.

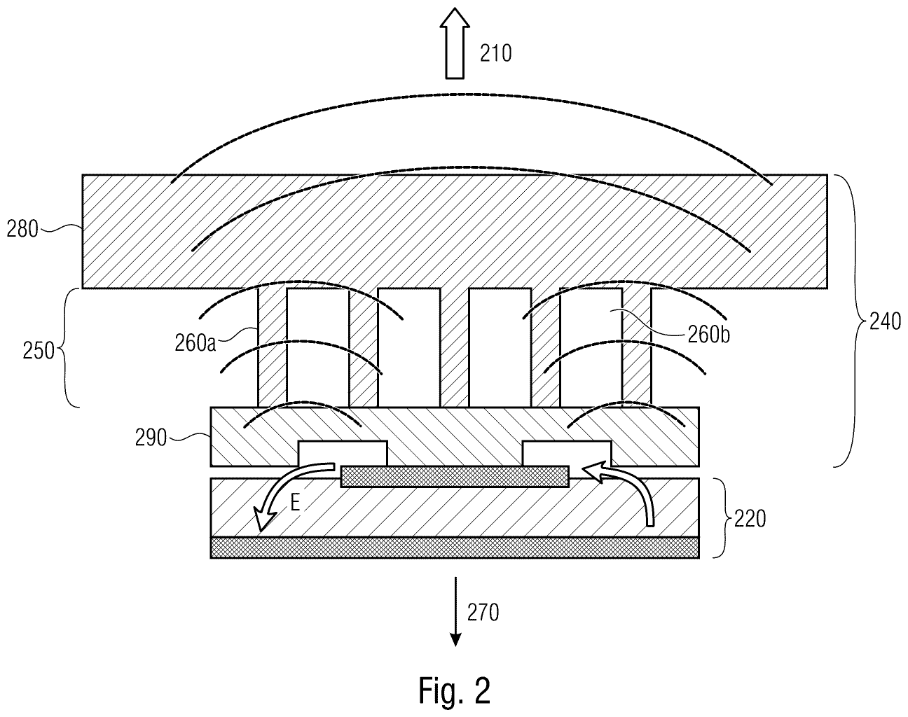

The higher permittivity dielectric regions 160a have for example, a relative permittivity greater than 2 or preferably between 2.5 and 4, such as polymer or polycarbonate or quartz or Teflon or PEEK materials. The lower permittivity dielectric regions 160b have for example a relative permittivity less than or equal to 1.5. As shown in FIG. 2, the lower permittivity dielectric region may also comprise air.

### Embodiments According to FIG. 2

FIG. 2 shows a schematic representation of an embodiment of a pusher 240, similar to the pusher 140 of FIG. 1, with an antenna 220 of the DUT. The pusher comprises a spacer 290, a structure 250 of higher permittivity dielectric regions 260a and lower permittivity dielectric regions 260b and a dielectric slab 280.

The pusher 240 is configured to repeatedly push DUTs 220, similar to the DUT 110 of FIG. 1, into a DUT-socket. The DUTs comprise at least an antenna 220 or an antenna array transmitting or receiving electromagnetic waves 210.

The spacer 290 of the pusher is attached to the pusher structure 250 and configured to be in-between the structure 250 and the DUT or the antenna 220 of the DUT. The spacer is perpendicular within a tolerance of +/−15° to the higher permittivity columns 260a or alternatively to the lower permittivity holes 260b of the pusher 240. The spacer is made of a mechanically soft lower permittivity dielectric material, with a relative permittivity of less than 1.5. The spacer is configured or machined so that the spacer avoids touching or approaching close-by or within a distance of 1/10 of a wavelength of an electromagnetic wave transmitted or received by the antenna 220, a conductive edge of the antenna of the DUT. The conductive edge might be a metallic edge of the antenna structure, which contributes strongly to the radiation.

The dielectric slab 280 is attached to the higher permittivity dielectric columns 260a and is arranged transversal or perpendicular within a tolerance of +/−15° to the pushing direction 270.

The dielectric slab 280 of the pusher 240 is configured to mechanically support at least the higher permittivity dielectric columns 260a of the structure 250. In order to remain transparent or near to transparent for electromagnetic waves 210 transmitted or received by the antenna 220, the dielectric slab 280 has a thickness which equals an integer multiple of half a wavelength of the electromagnetic wave 210 in the dielectric material of the dielectric slab 280. This calculates to a free space wavelength divided by the square root of relative permittivity of the dielectric. The tolerance of the thickness is 1/10 of a wavelength of an electromagnetic wave transmitted or received by the antenna 220, e.g. at a center frequency of the operation frequency band of the DUT.

The structure 250 of the pusher is similar to the pusher structure 150 of FIG. 1, in which the length in the pushing direction of the higher permittivity dielectric columns 260a or of the lower permittivity dielectric holes 260b is between 0.5 and 2 free space wavelengths of an electromagnetic wave transmitted or received by the antenna 220 of the DUT.

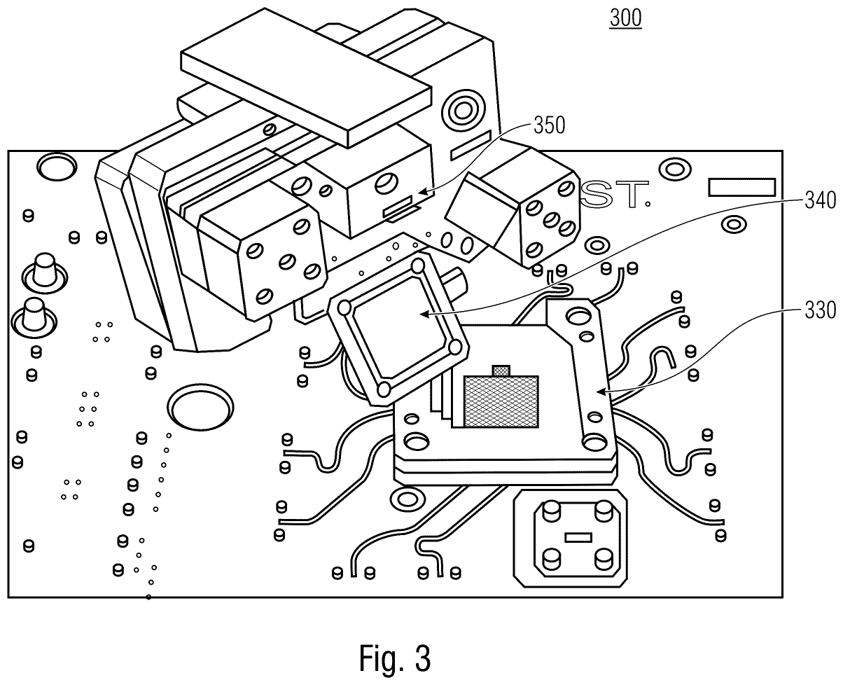

The pusher 240 can also be used in a test arrangement, similar to the test arrangement 100 of FIG. 1. A photo of the test arrangement with a pusher is to be found in FIG. 3.

### Embodiment According to FIG. 3

FIG. 3 shows a photo of an embodiment of a test arrangement 300, similar to the test arrangement 100 of FIG. 1. The test arrangement 300 comprises a pusher 340, similar to the pusher 140 of FIG. 1 or the pusher 240 of FIG. 2, and a DUT socket 330. The DUT of the test arrangement 300 is not shown, but FIG. 3 further shows a test antenna 350 of the automatic test equipment (ATE), which is configured to conduct over the air (OTA) tests or measurements on the DUT.

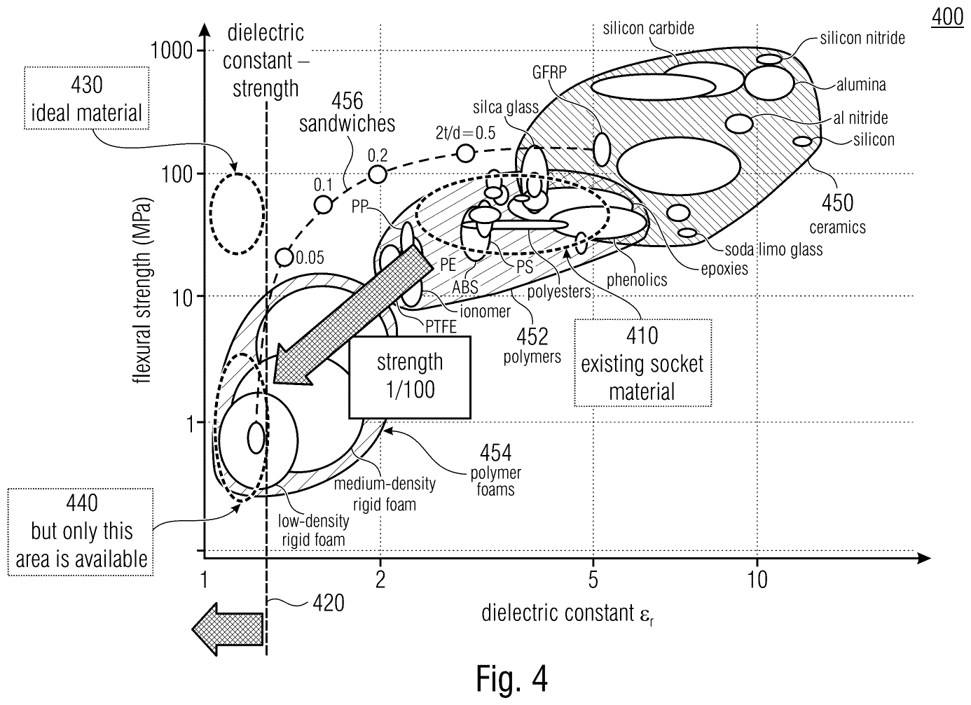

### Dielectric Constant-Strength Diagram According to FIG. 4

FIG. 4 shows a Dielectric constant-Strength diagram 400 in which abscissa-values represent dielectric constant values, and ordinate-values represent flexural strength values. Different materials are represented in this diagram, such as ceramics 450, polymers 452, polymer foams 454 and sandwiches 456. Existing pusher (or socket) materials 410, ideal pusher material 430 and available pusher materials 440 are also marked on this diagram.

It is shown that the existing pusher (or socket) materials 410 have a satisfactory flexural strength, but their dielectric constant is higher than ideal. A satisfactory dielectric constant would be on the left side of the line 420, or less than or equal to 1.5. The place of the ideal material 430 is illustrated in the diagram, but there are no known materials to match these requirements. Existing material with a dielectric constant of less than or equal to 1.5 is a type of polymer foam, with a flexural strength of 1/100^{th} of the existing or conventional pusher materials 410. The available materials 440 with a low dielectric constant, illustrated in the diagram, do not have the preferred flexural strength.

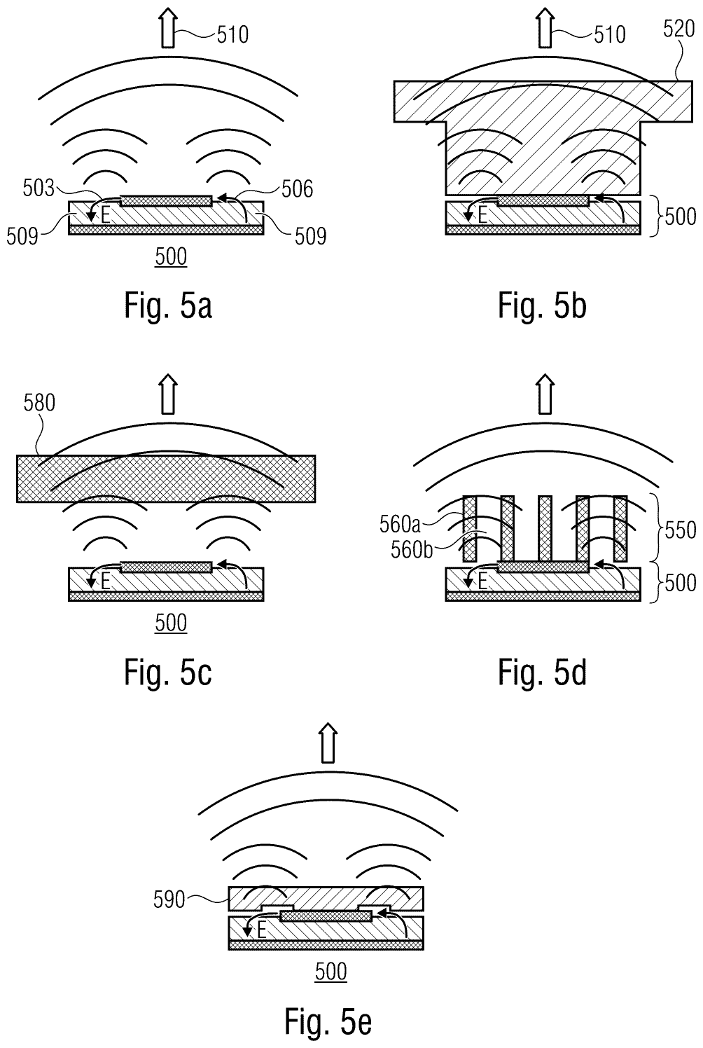

An ideal material, fulfilling the features of a low dielectric constant, e.g. lower than 1.5 and a higher flexural strength, higher than 30 MPa, is not known yet, and therefore an improved design concept is required. The design concepts applied in the pusher 240 of FIG. 2 is a combination of all the new ideas or design concepts of FIG. 5.

### Design Concept According to FIG. 5

FIG. 5a-e shows a schematic representation of existing and new pusher design concepts.

FIG. 5a shows the initial state, e.g. a patch antenna 500 without any pusher. The patch antenna 500 serves as a characteristic example of a planar antenna. It features two opposite radiating edges 503, 506 with an electric field 509 primarily perpendicular to these edges. Operating frequency and feed impedance are determined by the resonance of the electromagnetic field 509, which is enclosed between the ground and the patch and between the two radiating edges 503, 506.

That is, FIG. 5a shows an initial arrangement of a single patch antenna 500 without any pusher. The antenna radiates or transmits electromagnetic waves 510 which is preferred not to be affected by a pusher in an ideal test arrangement.

FIG. 5b shows the patch antenna 500 of FIG. 5a with a conventional pusher 520, with a conventional design concept, having a whole or solid block of a pusher 520 configured to push the DUT-antenna 500 into the DUT socket. The conventional pusher 520 is made of a material, which is an existing pusher material 410 of FIG. 4. In this conventional design, the dielectric loading of the radiating edges, or their close proximity, affects the resonance of the DUT-antenna 500. The dielectric pusher 520 will change the resonance of the DUT-antenna 500, thereby changing the feed impedance and radiation behavior of the DUT-antenna 500. If the pusher is large, compared to wavelength, and having a not-small permittivity, it is preferred to avoid arbitrary resonances within the pusher itself, which would eventually lead to significant or sometimes disastrous changes of the radiation and of the feed characteristics.

In order to have a pusher which avoids changing the resonance of the DUT-antenna 500 and thereby changing the feed impedance and radiation behavior, three dielectric structural features of a pusher with their particular electromagnetic features are introduced in the following three figures FIG. 5c-e.

FIG. 5c shows a dielectric slab 580 of a solid, mechanically strong, higher-permittivity dielectric material, placed parallel to the antenna aperture plane of the DUT-antenna 500. The thickness of the slab 580 equals, within a tolerance of 1/10 a wavelength of an electromagnetic wave transmitted or received by the DUT-antenna 500, an integer multiple of a half wavelength of the electromagnetic wave in the dielectric material of the dielectric slab 580.

The distance between the DUT-antenna 500 and the dielectric slab 580 is at least one wavelength of the electromagnetic wave transmitted or received by the DUT-antenna 500. The solid, mechanically strong, higher-permittivity dielectric material, which is required for mechanical stability, is not intended to touch the radiating slots or the metallic or conductive edges of the antenna aperture plane, as this leads to detuning the feed impedance. The conductive edge might be a metallic edge of the antenna structure, which contributes strongly to the radiation.

FIG. 5d shows a patch antenna 500 with a pusher structure 550, in which regions of higher permittivity dielectric material 560a are separated by air or by regions of lower permittivity dielectric material 560b. The structure 550 offers a lower effective permittivity to an electric field parallel to the extension of the higher permittivity dielectric columns 560a, compared to a higher effective permittivity for an electric field perpendicular to the extension of the higher permittivity dielectric columns 560a.

Provided the direction of an electric field is known, then the appropriately oriented structure 550 of columns of higher permittivity dielectric material 560a can have less influence on the DUT-antenna 500 performance. This applies for example for a field configuration as shown for the antenna 500.

FIG. 5e shows a DUT patch antenna 500 with a lower-permittivity dielectric spacer 590. A DUT with the patch antenna 500 is configured to be pushed by the spacer 590 or spacer layer 590 into a DUT socket.

The surface of planar antennas comprise, for example, dielectric surface areas, metal edges and metal surface areas. In terms of touching the surface with a dielectric pusher, the most sensitive areas are the metal edges and the dielectric areas close to them, as these may form radiating edges or slots, by the metal surfaces are rather non-critical.

Some structured dielectric spacer or spacer layer or sheet provides mechanical contacts between the planar antenna surface and the pusher only in the metal areas and in non-critical dielectric areas of the antenna surface. It is preferred to leave the radiating edges or slots without direct contact, providing some small air spacer volume above these edges or slots.

The concept's ideas of FIGS. 5c and 5e are rather obvious and straightforwardly implemented, while the tradeoff between efforts and benefits is further quantified by the idea of FIG. 5d. The design concepts of FIG. 5a-e are simulated in the following figures.

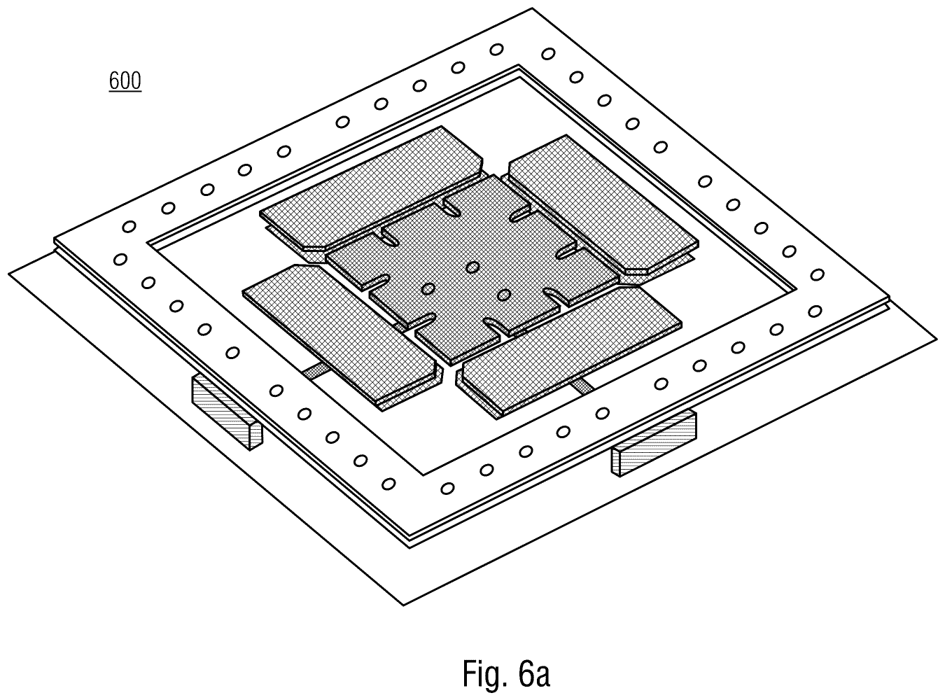

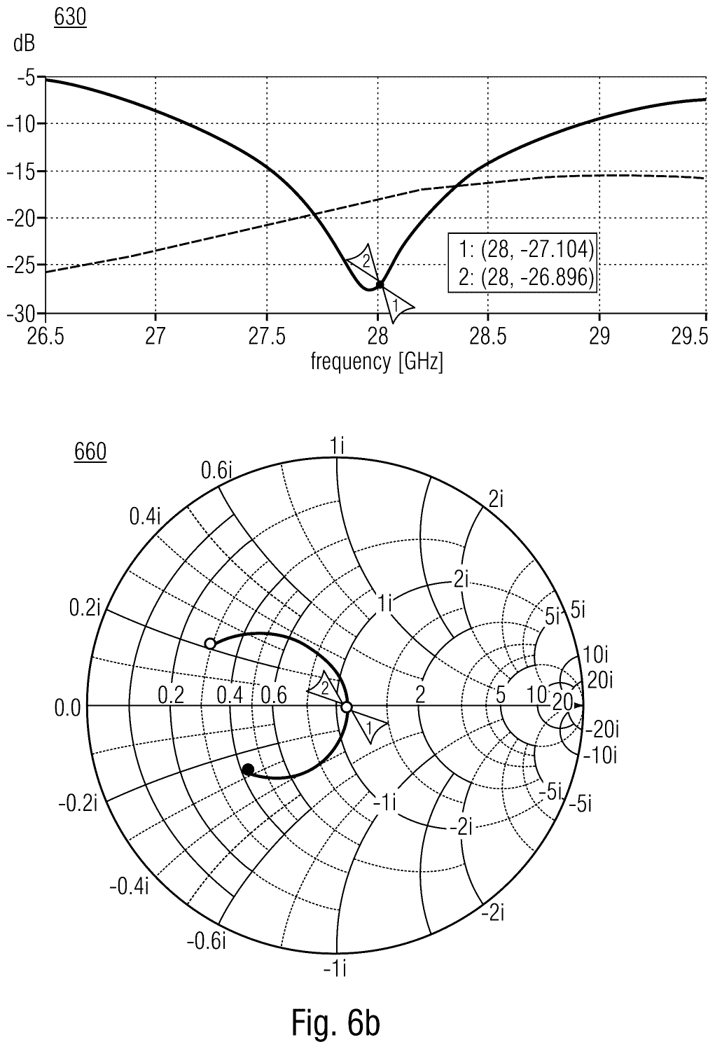

### Antenna Simulation According to FIG. 6

FIG. 6a shows a 3D simulation of a DUT with a dual-polarized patch antenna, which is a possible example of the patch antenna 500 of FIG. 5. The example antenna 600 used in FIG. 6 for quantifying performance in a simulation using electromagnetic field simulation software. The example antenna 600 is a dual-linearly polarized micro strip patch antenna. It is representative for the vast majority of planar antennas, as their operation and problems are common to all patch and slot antennas.

In the simulation a center frequency of operation of 28 GHz is used. The two feed lines are terminated in ports at a characteristic line impedance of about 35 Ohms.

FIG. 6b shows the simulated input reflection coefficient measurement results, in a frequency-reflection diagram 630 and on a Smith chart 660. The charts are showing the input reflection coefficients. Markers correspond to about (40.9+j1.0)Ω at 28 GHz.

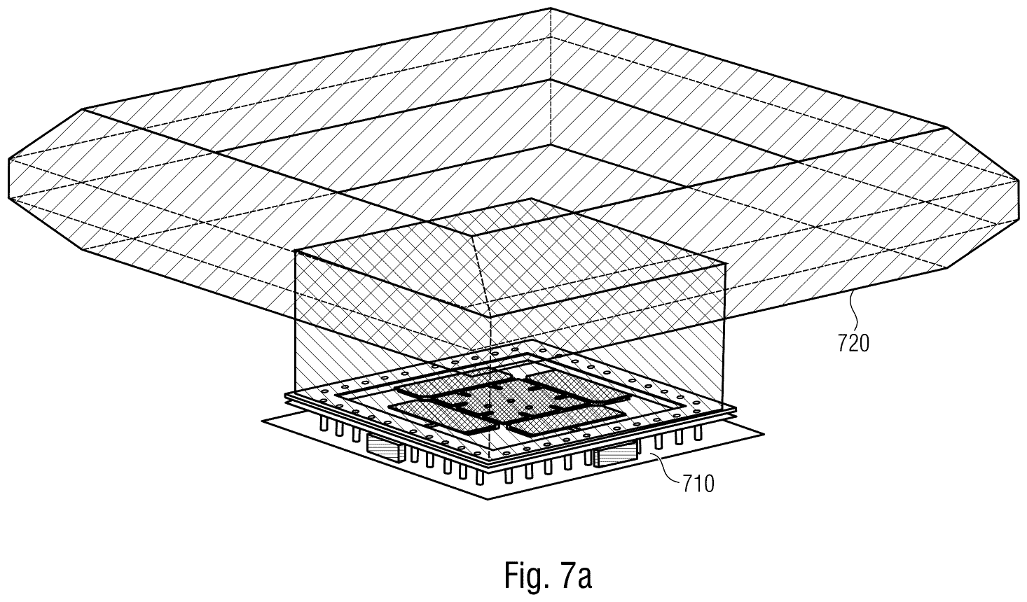

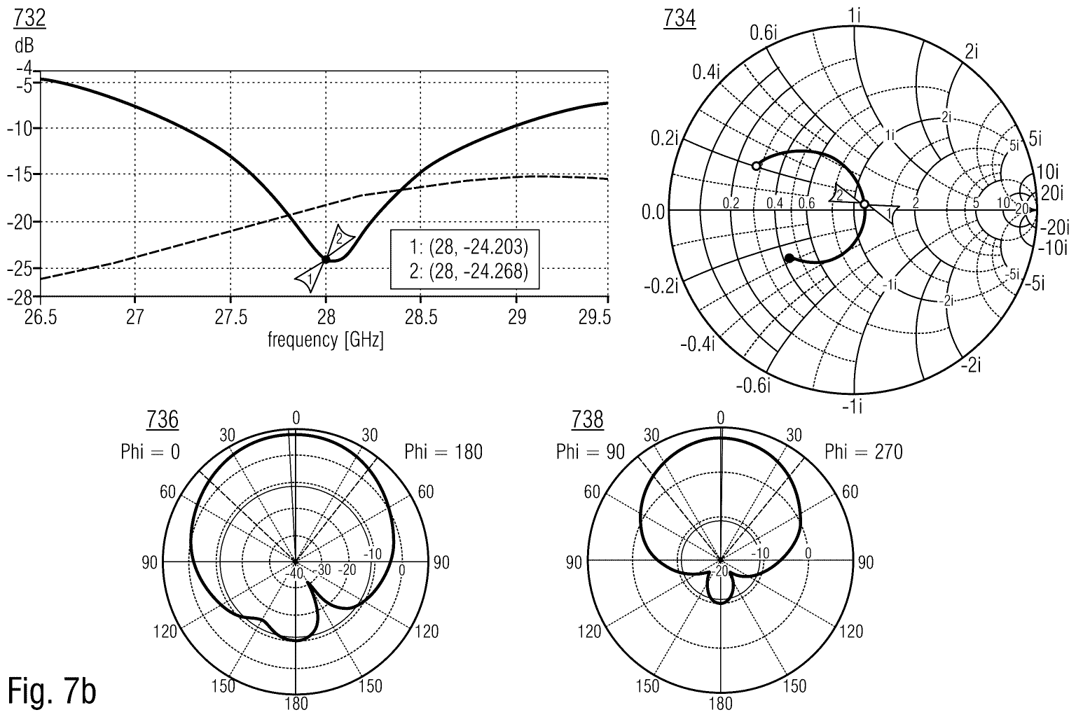

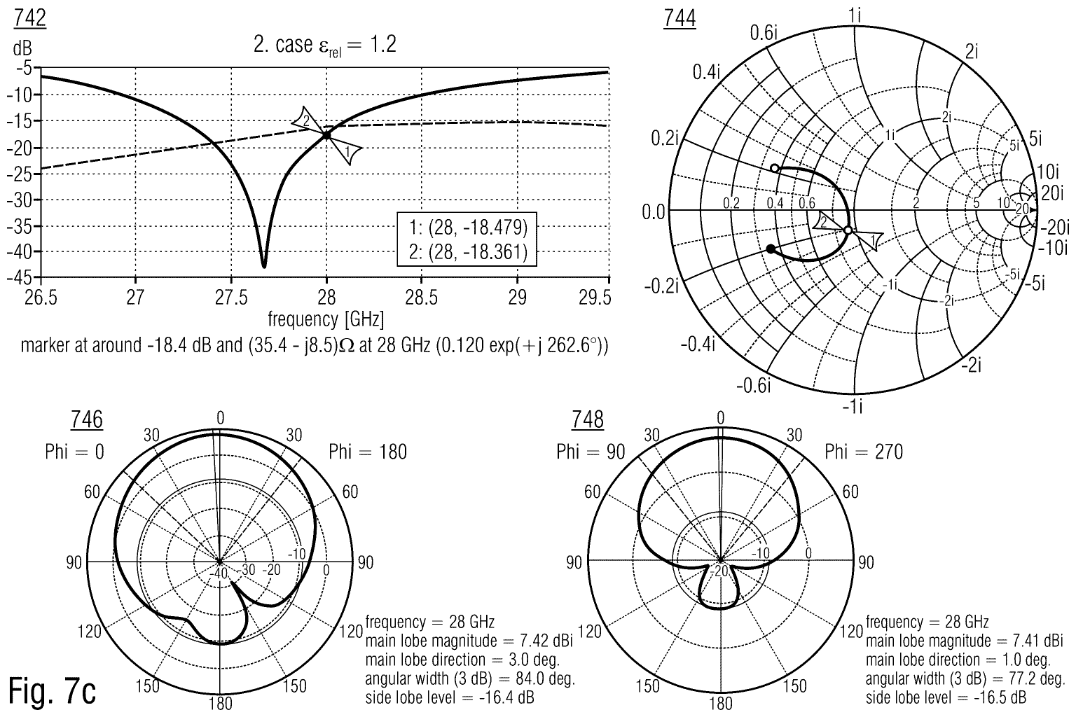

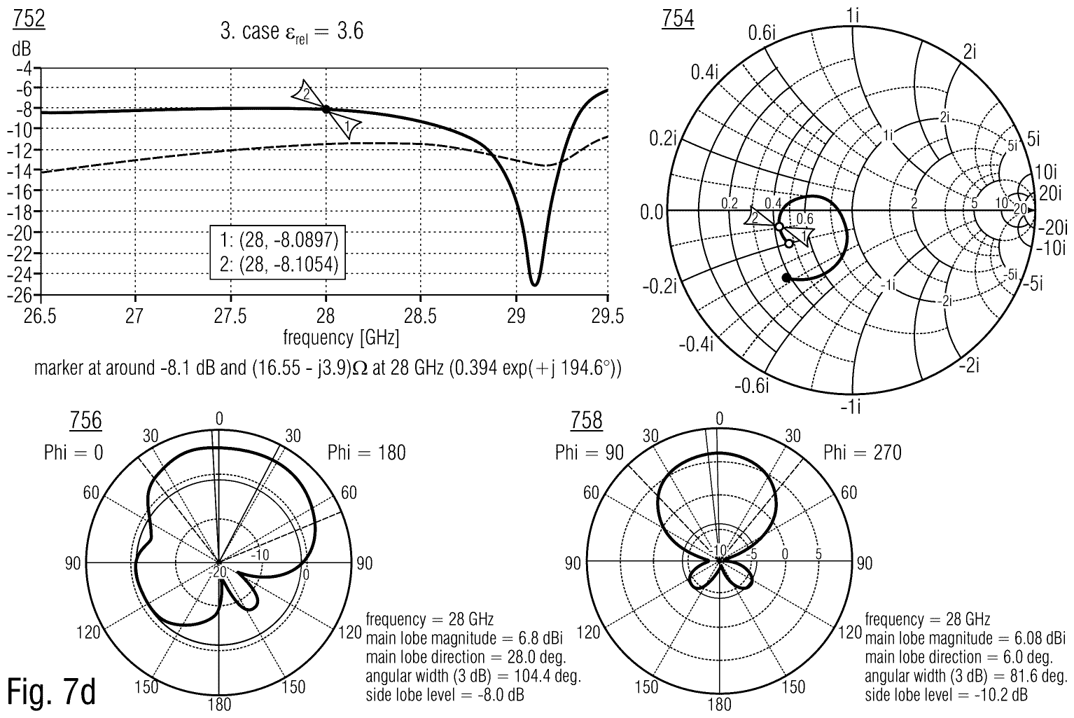

### Simulation of a Conventional Pusher According to FIG. 7

FIG. 7a shows a 3D simulation of an arrangement comprising a patch antenna 710 of a DUT, similar to the patch antenna 600 of FIG. 6, and a conventional solid dielectric pusher 720 configured to mechanically push a main surface of the DUT or the DUT-antenna into a DUT-socket, also shown in the design concept of FIG. 5b.

FIGS. 7b-d show results of simulated input reflection coefficient measurements conducted on the arrangement of FIG. 7a using different pushers, e.g. the pushers have different relative permittivity. In simulations a center frequency of operation of 28 GHz is used. The two feed lines are terminated in ports at a characteristic line impedance of about 35 Ohms.

FIG. 7b shows the results of a simulated input reflection coefficient measurement conducted on the first case of FIG. 7a, in which the pusher is made of a material with a relative permittivity of 1.0, such as air or vacuum. This equals to the fact that no pusher is present. Note, that the results presented in FIG. 6b, e.g. for an antenna of a device under test in air, is slightly different, because for an accurate comparison, in FIG. 7b the size of the computation domain is kept equal with or within all the simulations including the pusher. That is, in order to be able to compare the measurements of FIG. 7b-d, the domain of computation includes the pusher, while in the results presented in FIG. 6b it is not the case.

FIG. 7b shows input reflection coefficient measurement results of a simulation in which the pusher 720 is made of a material with a relative permittivity of 1, which is equal to not having a pusher. The simulation is taking account of the dimensions of the pusher, therefore the simulated measurement results are slightly different from the simulated measurement results presented in diagram 630 and Smith Chart 660 of FIG. 6.

The simulated measurement results of the input reflection coefficient is shown in the diagram 732 and in the Smith chart 734. Markers are at around −24.2 dB and (42.3+j1.2)Ω at 28 GHZ (0.0615 exp(+j 13.7°)).

The radiation pattern in two exemplary, perpendicular cut-planes for one selected polarization of the dual-polarized antenna are shown in the diagrams 736, 738.

Radiation pattern results for the first cut-plane is:
Frequency: 28 GHZ,
main lobe magnitude: 7.12 dBi,
main lobe direction: 3.0 deg.,
angular width (3 dB): 86.1 deg., and
side lobe level: −17.8 dB.

Radiation pattern results for the second cut-plane is:
Frequency: 28 GHZ,
main lobe magnitude: 7.11 dBi,
main lobe direction: 1.0 deg.,
angular width (3 dB): 78.4 deg.,
side lobe level: −17.7 dB.

FIG. 7c shows the results of a simulated input reflection coefficient measurement conducted on the second case of FIG. 7a, in which the pusher 720 is made of a material with a relative permittivity of 1.2, for example a dielectric foam material. Similar to the first case, the results of the simulated reflection coefficient measurements are presented on the diagram 742 and on the Smith chart 744. Markers are at around −18.4 dB and (35.4−j8.5)Ω at 28 GHZ (0.120 exp(+j 262.6°)).

Radiation pattern in two exemplary, perpendicular cut-planes for one selected polarization of the dual-polarized antenna are shown in the charts 746, 748.

Radiation pattern results for the first cut-plane is:
Frequency: 28 GHZ,
main lobe magnitude: 7.42 dBi,
main lobe direction: 3.0 deg.,
angular width (3 dB): 84 deg., and
side lobe level: −16.4 dB.

Radiation pattern results for the second cut-plane is:
Frequency: 28 GHZ,
main lobe magnitude: 7.41 dBi,
main lobe direction: 1.0 deg.,
angular width (3 dB): 77.2 deg.,
side lobe level: −16.5 dB.

FIG. 7d shows the results of a third case, in which the pusher 720 is made of a material with a relative permittivity of 3.6, which might be a Polyetheretherketon (PEEK) material. The results of the simulated reflection coefficient measurements are presented on the diagram 752 and on the Smith chart 754. Markers are at around −8.1 dB and (16.55−j3.9)Ω at 28 GHZ (0.394 exp(+j 194.6°)).

Radiation pattern in two exemplary, perpendicular cut-planes for one selected polarization of the dual-polarized antenna are shown in the charts 756, 758.

Radiation pattern results for the first cut-plane is:
Frequency: 28 GHZ,
main lobe magnitude: 6.8 dBi,
main lobe direction: 28.0 deg.,
angular width (3 dB): 104.4 deg., and
side lobe level: −8 dB.

Radiation pattern results for the second cut-plane is:
Frequency: 28 GHZ,
main lobe magnitude: 6.08 dBi,
main lobe direction: 6.0 deg.,
angular width (3 dB): 81.6 deg.,
side lobe level: −10.2 dB.

In order to summarize the design concept used by conventional pushers 720, the simulated measurement results of FIG. 7b are compared to the simulated measurement results of FIG. 7c and FIG. 7d.

Comparing the first and second case, or the simulated measurement results of FIG. 7b and FIG. 7c, the feed reflection coefficient changed in the complex plane by 0.153, gain increased from 7.1 dBi to 7.4 dBi, and the beam width reduced from 86° to 84° (E-plane) respectively from 78° to 77° (H-plane). Such variation, and thus, such influence of the pusher is clearly acceptable. A material with a relative permittivity of 1.2, however, is mechanically not stiff enough.

Comparing the first and the third case, that is the simulated measurement results of FIG. 7b to the simulated measurement results of FIG. 7d, the feed reflection coefficient moved in the complex plane by 0.455, gain increase from 7.1 dBi to 6.8 dBi and beam width changed from 86° to 104° (E-plane) and respectively from 78° to 82° (H-plane). Such variation and thus, such influence of the pusher is too high, e.g. unacceptable.

The simulated measurement results, as shown in FIG. 7b-d, of a conventional pusher, shown in FIG. 7a, is a demonstration that further design concepts or their combination are required.

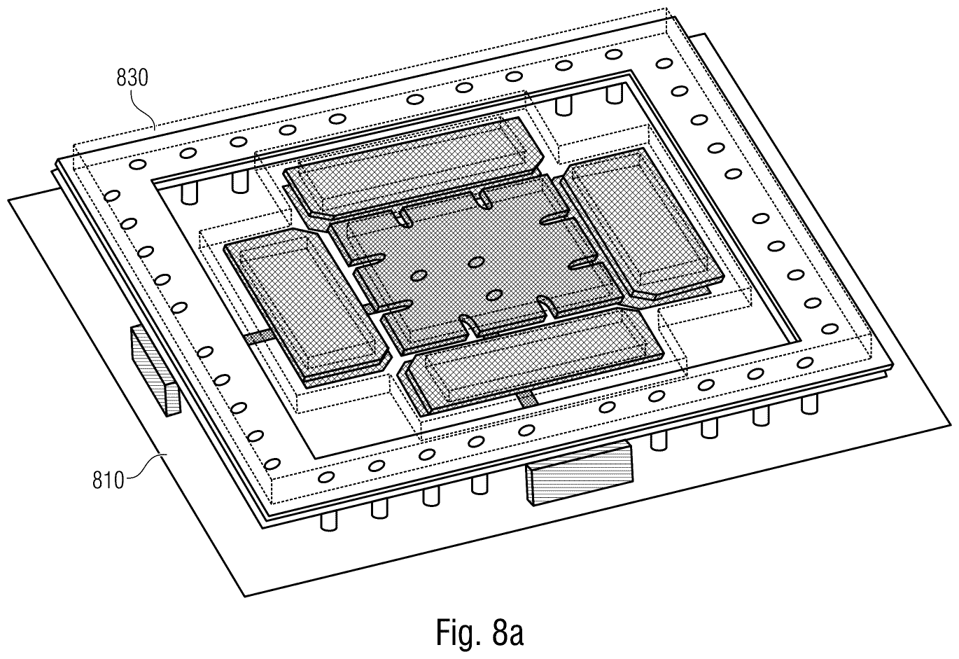

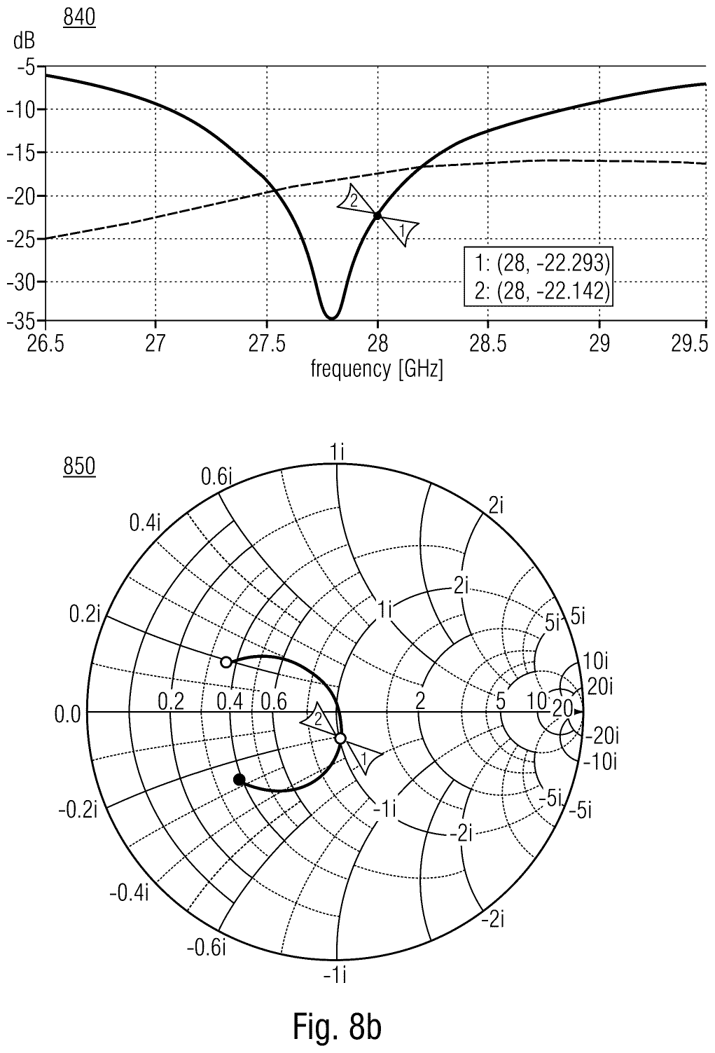

### Simulation of the Spacer According to FIG. 8

FIG. 8 shows a 3D simulation of a patch antenna 810, similar to the patch antenna 600 of FIG. 6, and a spacer 830, configured to push the DUT into a DUT-socket. The simulated spacer 830 is a low-permittivity spacer with a relative permittivity of 1.3, and an overall thickness of 300 micrometers. The spacer is considered to be touching the antenna surface. Further, the spacer provides (air-filled) trenches or cutouts of a depth of, for example, 150 micrometers along radiating edges or slots, with a trench width of, for example, 300 micrometers.

Results of the simulated reflection coefficient measurements are shown in the diagram 840 and in the Smith chart 850. Markers are at around −22.2 dB and (38.47-j5.8)Ω at 28 GHZ (0.0077 exp(+j 283.5°)).

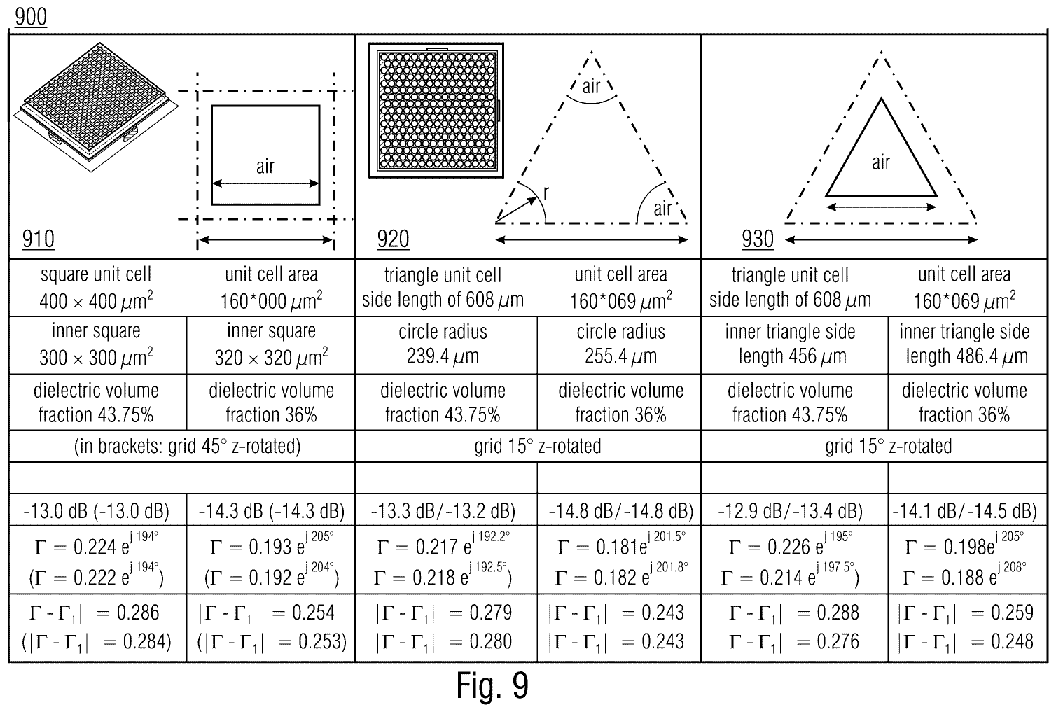

### Structure Design Simulation According to FIG. 9

FIG. 9 shows a table 900 comparing properties of three different potential structures of a pusher. The three pusher-structures is structured dielectric, which is known to be semi-isotropic in xy-planes for operation with both orthogonal polarizations. The three different choices or different design concepts of the structure are a) a square grid with square-cross-section air-filled cylinders 910, b) triangle grid with circular cross-section air-filled cylinders 920, and c) triangle grid with triangle-cross-section air-filled cylinders 930. These three choices 910, 920, 930 are compared within the table 900 of FIG. 9.

Care has been taken for obtaining a fair comparison, that is why in table 900 the volume fraction of air and of the dielectric has been chosen to be equal for all three choices 910, 920, 930, and also the volume of unit cells are chosen to be about equal for all the choices 910, 920, 930. Each design concept choices 910, 920, 930 have been tested with two different dielectric volume fractions of 43.75% and 36%.

In particularly, choice 910, e.g. the square grid with square-cross-section air-filled cylinders, has a square unit cell of 400×400 μm², making up a unit cell area of 160,000 μm². With an inner square of 300×300 μm² the choice 910 has a dielectric volume fraction of 43.75% or with an inner square of 320×320 μm² the dielectric volume fractions becomes 36%. In both cases the grid is 45° z-rotated, e.g. rotated in the z-direction.

In the first case, e.g. with a dielectric volume fraction of 43.75%, the values −13.0 dB and −13.0 dB are measured, which results in the feed reflection coefficients of Γ=0.224 e^{j194°} and Γ=0.222 e^{j194°} and in the change of feed reflections of |Γ−Γ₁|=0.286 and |Γ−Γ₁|=0.284.

In the second case, e.g. with a dielectric volume fraction of 36%, the values −14.3 dB and −14.3 dB are measured, which results in the feed reflection coefficients of Γ=0.193 e^{j205°} and Γ′=0.192 e^{j204°} and in the change of feed reflections of |Γ−Γ₁|=0.254 and |Γ−Γ₁|=0.253.

In particularly, choice 920, e.g. the triangle grid with circular cross-section air-filled cylinders, has a triangle unit cell with a side length of 608 μm, making up a unit cell area of 160,069 μm². With a circle radius of 239.4 μm the choice 920 has a dielectric volume fraction of 43.75% or with a circle radius of 255.4 μm the dielectric volume fractions becomes 36%. In both cases the grid is 15° z-rotated, e.g. rotated in the z-direction.

In the first case, e.g. with a dielectric volume fraction of 43.75%, the values −13.3 dB and −13.2 dB are measured, which results in the feed reflection coefficients of Γ=0.217 e^{j192.2°} and Γ=0.218 e^{j192.5°} and in the change of feed reflections of |Γ−Γ₁|=0.279 and |Γ−Γ₁|=0.280.

In the second case, e.g. with a dielectric volume fraction of 36%, the values −14.8 dB and −14.8 dB are measured, which results in the feed reflection coefficients of Γ=0.181 e^{j201.5°} and Γ=0.182 e^{j201.8°} and in the change of feed reflections of |Γ−Γ₁|=0.243 and |Γ−Γ₁|=0.243.

In particularly, choice 930, e.g. the triangle grid with triangle-cross-section air-filled cylinders, has a triangle unit cell with a side length of 608 μm, making up a unit cell area of 160,069 μm². With an inner triangle side length of 456 μm the choice 930 has a dielectric volume fraction of 43.75% or with an inner triangle side length of 486.4 μm the dielectric volume fractions becomes 36%. In both cases the grid is 15° z-rotated, e.g. rotated in the z-direction.

In the first case, e.g. with a dielectric volume fraction of 43.75%, the values −12.9 dB and −13.4 dB are measured, which results in the feed reflection coefficients of Γ=0.226 e^{j195°} and Γ=0.214 e^{j197.5°} and in the change of feed reflections of |Γ−Γ₁|=0.288 and |Γ−Γ₁|=0.276.

In the second case, e.g. with a dielectric volume fraction of 36%, the values −14.1 dB and −14.5 dB are measured, which results in the feed reflection coefficients of Γ=0.198 e^{j205°} and Γ=0.188 e^{j208°} and in the change of feed reflections of |Γ−Γ₁|=0.259 and |Γ−Γ₁|=0.248.

After reviewing the table, it can be concluded that a smaller volume fraction of a higher permittivity dielectric material, is more beneficial than a larger volume fraction of the higher permittivity dielectric material. Also, a triangular grid with cylindrical holes outperforms, e.g. is more transparent, than the other variants within the table 900 of FIG. 9. Further, comparing with other simulation cases to be discussed below, the smaller unit cell is better by a small amount, that is a structure with smaller unit cells results in a slightly more transparent structure.

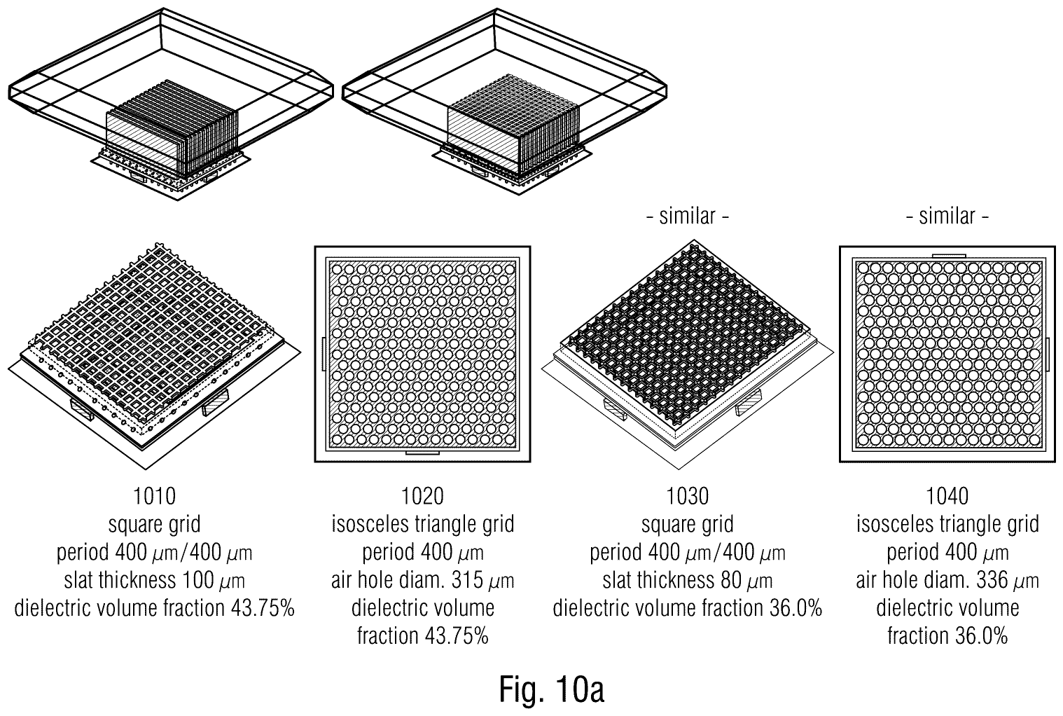

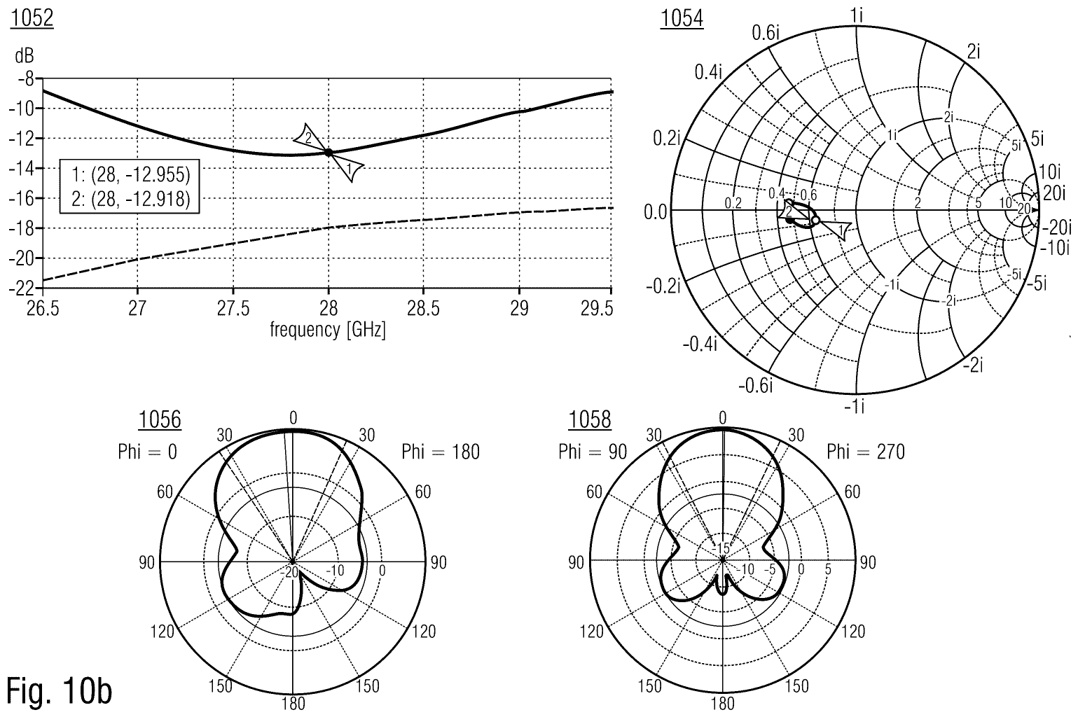

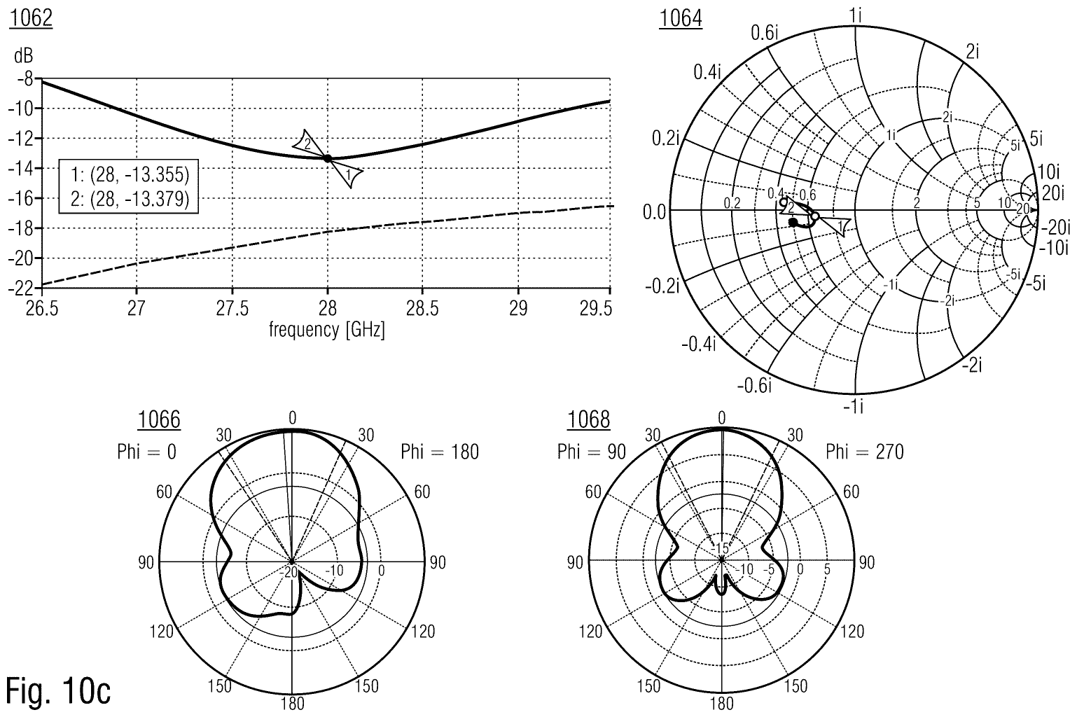

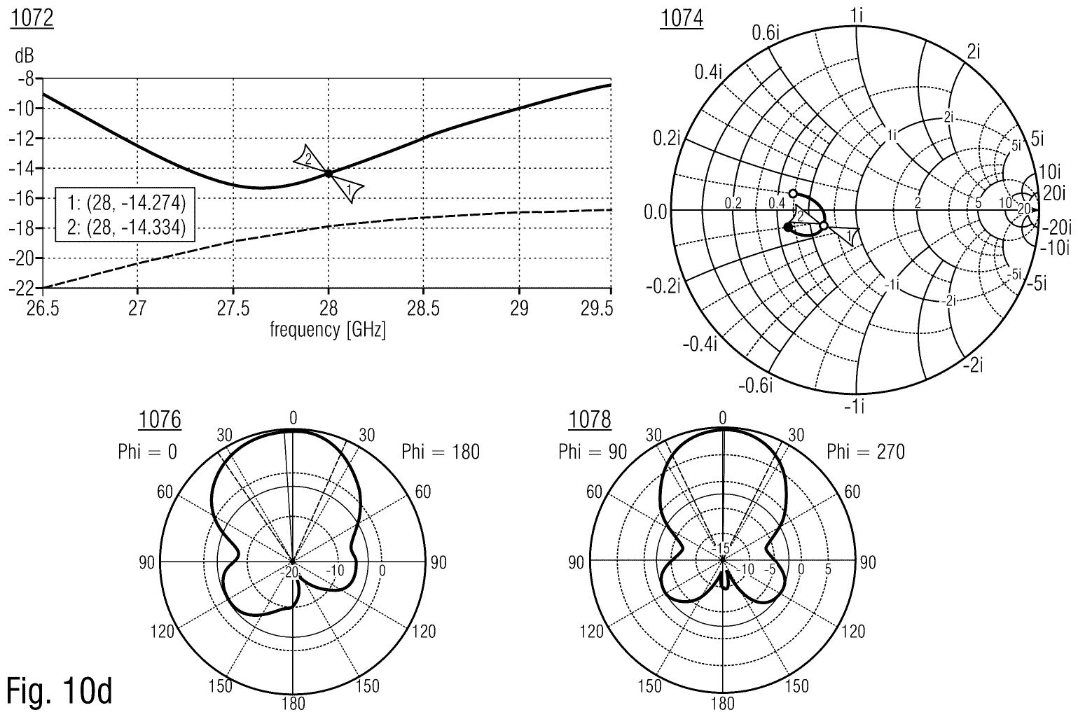

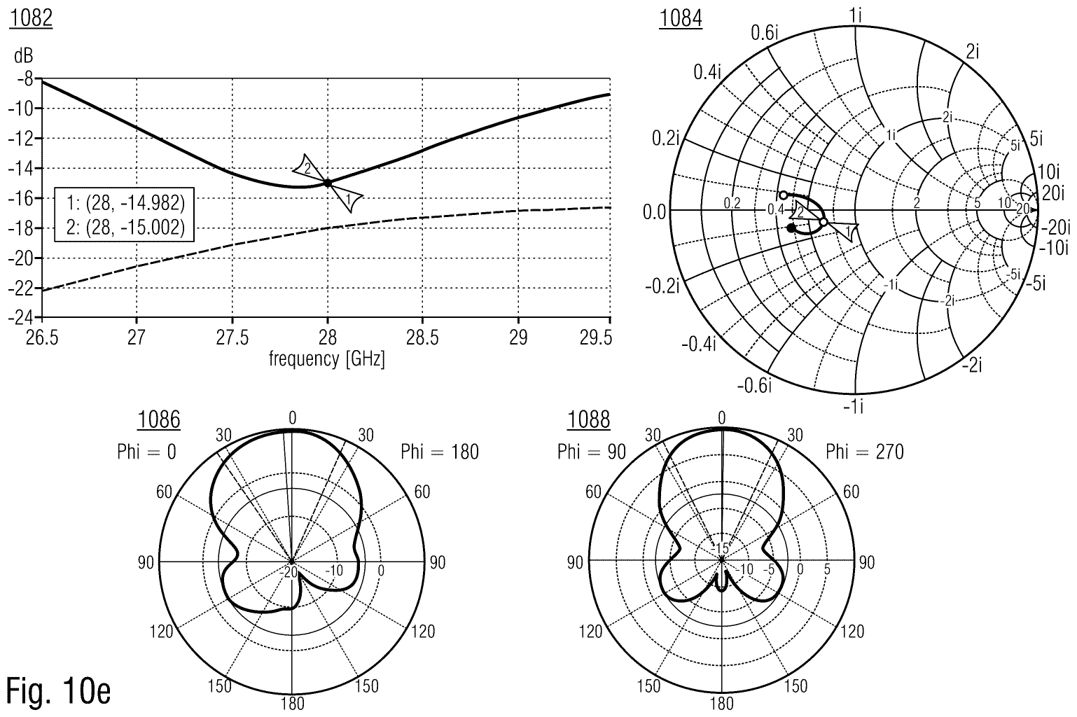

### Simulation of a Combination of Different Design Concepts According to FIG. 10

FIG. 10a shows simulations of simulated pushers with four different structures. In particularly a pusher with a structure of a) a square grid with a dielectric volume fraction of 43.75% 1010, b) an isosceles triangle grid with a dielectric volume fraction of 43.75% 1020, c) a square grid with a dielectric volume fraction of 36% 1030, and d) an isosceles triangle grid with a dielectric volume fraction of 36% 1040.

The results of simulated input reflection coefficient measurements on pushers with different structures 1010, 1020, 1030, 1040 are shown in FIGS. 10b-e. Each simulated pusher comprises a spacer and a dielectric slab with a thickness of λ/2 or a λ/2-plate. In all simulations, the spacer has a relative permittivity of 1.3 and the higher permittivity material of the structure and of the dielectric slab has a relative permittivity of 3.6.

The results of the simulated input reflection coefficient measurements on the pushers are shown in the following diagrams and in a Smith charts of FIGS. 10b-e. Also, radiation pattern in two exemplary, perpendicular cut-planes for one selected polarization of the dual-polarized antenna are shown in FIGS. 10b-e.

Results of simulated input reflection coefficient measurements on a pusher with a square grid structure with a dielectric volume fraction of 43.75% is shown in FIG. 10b. Diagram 1052 and Smith chart 1054 has a marker for port 1 and 2 at around −12.9 dB and (24.0−j 3.1)Ω at 28 GHz (0.225 exp(+j 195.6°)). Radiation pattern in two exemplary, perpendicular cut-planes for one selected polarization of the dual-polarized antenna are shown in the charts 1056 and 1058.

Radiation pattern results for the first cut-plane is:
Frequency: 28 GHZ,
main lobe magnitude: 9.88 dBi,
main lobe direction: 4.0 deg.,
angular width (3 dB): 57.7 deg., and
side lobe level: −13.0 dB.

Radiation pattern results for the second cut-plane is:
Frequency: 28 GHZ,
main lobe magnitude: 9.83 dBi,
main lobe direction: 0.0 deg.,
angular width (3 dB): 52.3 deg.,
side lobe level: −12.3 dB.

Results of simulated input reflection coefficient measurements on a pusher with an isosceles triangle grid with a dielectric volume fraction of 43.75% is shown in FIG. 10c. Diagram 1062 and Smith chart 1064 has a marker for port 1 and 2 at around −13.35 dB and (24.4−j 1.9)Ω at 28 GHZ (0.215 exp(+j 190°)). Radiation pattern in two exemplary, perpendicular cut-planes for one selected polarization of the dual-polarized antenna are shown in the charts 1066 and 1068.

Radiation pattern results for the first cut-plane is:
Frequency: 28 GHZ,
main lobe magnitude: 9.9 dBi,
main lobe direction: 4.0 deg.,
angular width (3 dB): 57.9 deg., and
side lobe level: −13.0 dB.

Radiation pattern results for the second cut-plane is:
Frequency: 28 GHZ,
main lobe magnitude: 9.82 dBi,
main lobe direction: 0.0 deg.,
angular width (3 dB): 52.0 deg.,
side lobe level: −12.6 dB.

Results of simulated input reflection coefficient measurements on a pusher with a square grid structure with a dielectric volume fraction of 36.0% is shown in FIG. 10d. Diagram 1072 and Smith chart 1074 has a marker for port 1 and 2 at around −14.3 dB and (26.1−j 4.45)Ω at 28 GHZ (0.193 exp(+j 205°)). Radiation pattern in two exemplary, perpendicular cut-planes for one selected polarization of the dual-polarized antenna are shown in the charts 1076 and 1078.

Radiation pattern results for the first cut-plane is:
Frequency: 28 GHZ,
main lobe magnitude: 9.95 dBi,
main lobe direction: 3.0 deg.,
angular width (3 dB): 57.8 deg., and
side lobe level: −13.3 dB.

Radiation pattern results for the second cut-plane is:
Frequency: 28 GHZ,
main lobe magnitude: 9.91 dBi,
main lobe direction: 1.0 deg.,
angular width (3 dB): 51.7 deg.,
side lobe level: −12.3 dB.

Results of simulated input reflection coefficient measurements on a pusher with an isosceles triangle grid with a dielectric volume fraction of 36.0% is shown in FIG. 10e. Diagram 1082 and Smith chart 1084 has a marker for port 1 and 2 at around −15.0 dB and (26.5−j 3.02)Ω at 28 GHZ (0.178 exp(+j 198°)). Radiation pattern in two exemplary, perpendicular cut-planes for one selected polarization of the dual-polarized antenna are shown in the charts 1086 and 1088.

Radiation pattern results for the first cut-plane is:
Frequency: 28 GHZ,
main lobe magnitude: 9.93 dBi,
main lobe direction: 4.0 deg.,
angular width (3 dB): 58.3 deg., and
side lobe level: −13.4 dB.

Radiation pattern results for the second cut-plane is:
Frequency: 28 GHZ,
main lobe magnitude: 9.87 dBi,
main lobe direction: 0.0 deg.,
angular width (3 dB): 51.6 deg.,
side lobe level: −12.5 dB.

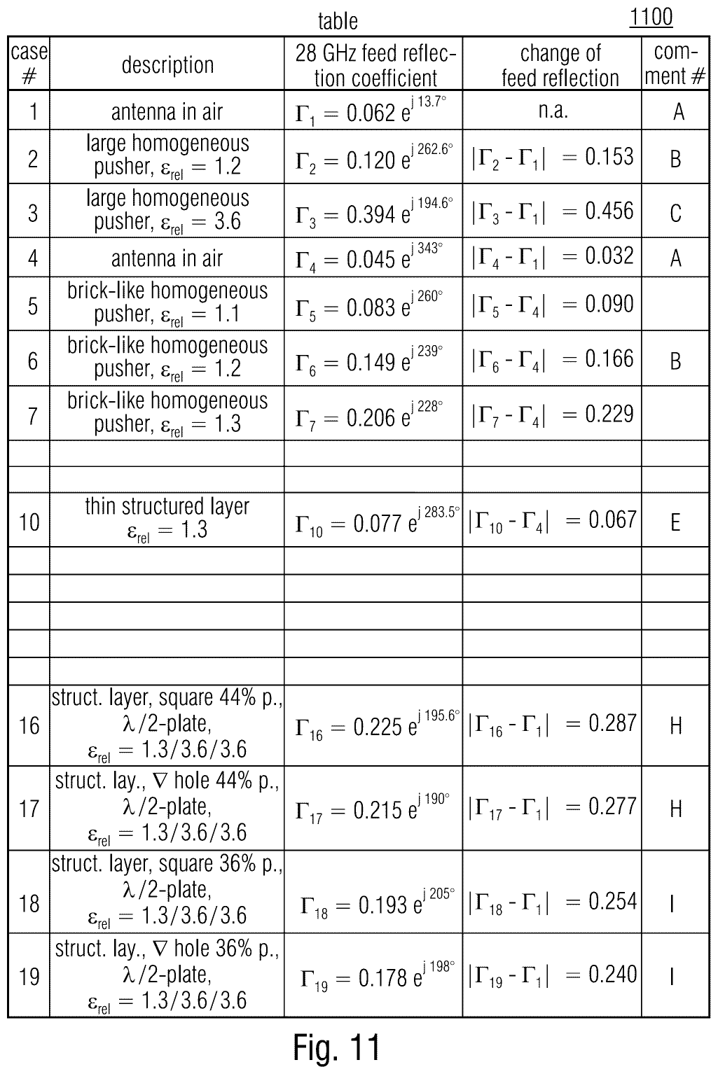

Further measurement results are presented in table 1100 of FIG. 11 in which changes of the feed reflection coefficient are compared.

### Measurement Results According to FIG. 11

FIG. 11 shows a comparison table 1100 with respect to the change of feed reflection coefficient. That is, for different cases, described in the column “description”, the 28 GHz feed reflection coefficient and the change of feed reflection is indicated in the table. Comments related to cases indicated by letters in the last column of the table are to be found below:
A A small difference between simulations of a structure “antenna only” (i.e., without any pusher) can be attributed to different size of “air volume” in the computational domain and to different mesh.
B According to measurements, using pusher made of homogeneous foam dielectric of permittivity εᵣₑₗ=1.2, such change of feed reflection is acceptable (although it is not known, to what extent a somewhat larger change would be acceptable, too).
C A material with permittivity of εᵣₑₗ=3.6, such as PEEK, when used for a homogeneous pusher, leads to completely unacceptable disturbance of the antenna.
E The thin structured spacer layer is supposedly made of foam (εᵣₑₗ=1.3), which is soft but stiff enough in small thickness (0.3 mm). This spacer layer is to be machined specifically depending on the layout of the antenna (array) aperture surface.
H For dual-polarized structures, the formerly one-dimensionally periodic layered-sheet pusher becomes two-dimensionally periodic. Thereby, it loses its key electromagnetic feature, namely, to avoid tangential E-field at dielectric-air boundaries. Unlike case #16, the case #17 uses triangular grid instead of square grid, thereby weakening the “problem of E-field-parallelism”, and with the same volume fraction, a better performance is obtained. While circular cylindrical holes are assumed (in view of manufacturability), holes of triangular cross-section would be even better, but not feasible.
I For dual-polarized structures, as for all structures, reducing the volume fraction of dielectric, e.g. increasing the volume fraction of air, is helpful in reducing the level of change of the reflection coefficient caused by the pusher.

Regarding the radiation pattern, a focusing effect, e.g. a higher directivity and narrower beam in a direction perpendicular to the antenna surface, is caused by the dielectric pusher. As long as this effect is small, it does not affect significantly negatively the testing application. With the exception of illustrative case no. 3, e.g. a full homogenous PEEK pusher, all other pushers cause small pattern changes only.

In conclusion, for dual-linear polarization antennas, the proposed electromagnetic features are valuable. The pusher might not be completely transparent, some antenna disturbance might be accepted or a reduced dielectric volume fraction might be realized in the structure or in the structured part of the pusher. The more the dielectric volume is reduced, the manufacturability will be more of an issue.

### Implementation Alternatives

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus. In some embodiments, one or more of the most important method steps may be executed by such an apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A pusher for use in an automated test equipment to mechanically push a device under test into a device under test socket, the pusher comprising:
higher permittivity dielectric regions, and
lower permittivity dielectric regions;
wherein the higher permittivity regions and the lower permittivity regions form
a structure of higher permittivity dielectric columns with lower permittivity dielectric regions between the columns, or
a structure of a higher permittivity dielectric block with lower permittivity dielectric holes; and
wherein the higher permittivity dielectric columns or the holes extend in a first direction, which is within +/−45° of a pushing direction.

2. The pusher according to claim 1,
wherein the higher permittivity dielectric columns or the holes are circular or square-shaped or triangle-shaped or cross-shaped.

3. The pusher according to claim 1,
wherein the structure comprises between 5 and 50 higher permittivity dielectric columns or holes per free space wavelength of an electromagnetic wave transmitted or received by an antenna of the device under test.

4. The pusher according to claim 1,
wherein the structure comprises a matrix of higher permittivity dielectric columns or holes, or
wherein the structure comprises a regular grid of higher permittivity dielectric columns or holes.

5. The pusher according to claim 1,
wherein the structure comprises between 9 vol. % and 66.6 vol. % higher permittivity dielectric regions and between 91 vol. % and 33.3 vol. % lower permittivity dielectric regions.

6. The pusher according to claim 1, further comprising:
a surface configured to touch the device under test;
wherein the surface of the pusher, which is configured to touch the device under test, is formed so that the pusher avoids touching or approaching, within a distance of 1/10 of a wavelength of an electromagnetic wave transmitted or received by an antenna of the device under test, a conductive edge of an antenna of the device under test.

7. The pusher according to claim 1, further comprising:
a spacer;
wherein the spacer is configured to be in between the structure and the device under test; and
wherein the spacer is perpendicular, within a tolerance of +/−15°, to the columns or holes, or
wherein the spacer is parallel, within a tolerance of +/−15°, to a surface of the device under test to be pushed by the pusher.

8. The pusher according to claim 7,
wherein the spacer comprises a relative permittivity less than or equal to 1.5.

9. The pusher according to claim 7,
wherein the spacer comprises a thickness of between 50 micrometer and 500 micrometer.

10. The pusher according to claim 1, further comprising:
a dielectric slab;
wherein the dielectric slab is transversal to or perpendicular, within a tolerance of +/−15°, to the pushing direction; and
wherein the dielectric slab is configured to mechanically support the higher permittivity dielectric columns or the higher permittivity dielectric block.

11. The pusher according to claim 1,
wherein the higher permittivity dielectric regions comprise a relative permittivity greater than 2.

12. The pusher according to claim 1,
wherein the higher permittivity dielectric regions are made of polymer or of polycarbonate or of quartz or of Teflon or of PEEK material.

13. The pusher according to claim 1,
wherein the lower permittivity dielectric regions comprise a relative permittivity less than or equal to 1.5.

14. The pusher according to claim 1,
wherein the lower permittivity dielectric regions comprise air.

15. The pusher according to claim 1,
wherein the pushing direction is perpendicular, within a tolerance of +/−15°, to a far-field direction of an electrical field in a main lobe of an antenna of the device under test, or
wherein the pushing direction is perpendicular, within a tolerance of +/−15°, to a main surface of device under test, or
wherein the pushing direction is perpendicular, within a tolerance of +/−15°, to a main surface of device under test socket.

16. A test arrangement for testing a device under test, the test arrangement comprising:
a device under test,
a device under test socket, and
a pusher according to claim 1;
wherein the device under test comprises an antenna;
wherein the device under test is pushed into the device under test socket by the pusher in order to test the device under test.

17. The test arrangement according to claim 16,
wherein the pusher comprises a dielectric slab;
wherein the dielectric slab is transversal to or perpendicular, within a tolerance of +/−15°, to the pushing direction;
wherein the dielectric slab is configured to mechanically support the higher permittivity dielectric columns or the higher permittivity dielectric block;
wherein the dielectric slab of the pusher comprises a thickness which equals, within a tolerance of 1/10 a wavelength of an electromagnetic wave transmitted or received by the antenna of the device under test, to an integer multiple of a half a wavelength of the electromagnetic wave in the dielectric material of the dielectric slab transmitted or received by the antenna of the device under test; and
wherein a distance between the dielectric slab and the surface of the antenna of the device under test is at least one wavelength of the electromagnetic wave transmitted or received by the antenna of the device under test.

18. The test arrangement according to claim 16,
wherein a length of the higher permittivity dielectric columns or of the holes of the pusher in the pushing direction is between 0.5 times a free space wavelength of an electromagnetic wave transmitted or received by the antenna of the device under test and 2 times the free space wavelength of the electromagnetic wave transmitted or received by the antenna of the device under test.

19. The test arrangement according to claim 16,
wherein the pusher comprises a spacer;
wherein the spacer is configured to be in between the structure and the device under test;
wherein the spacer is perpendicular, within a tolerance of +/−15°, to the columns or holes, or
wherein the spacer is parallel, within a tolerance of +/−15°, to a surface of the device under test to be pushed by the pusher; and
wherein the spacer is further configured to touch the device under test, so that the spacer avoids touching or approaching, within a distance of 1/10 of a wavelength of an electromagnetic wave transmitted or received by the antenna of the device under test, a conductive edge of the antenna of the device under test.

20. A method for mechanically pushing a device under test into a device under test socket of an automated test equipment, the method comprising:
mechanically pushing the device under test into the device under test socket with a pusher,
wherein the pusher comprises
a structure of higher permittivity dielectric columns with lower permittivity dielectric regions between the columns, or
a structure of a higher permittivity dielectric block with lower permittivity dielectric holes; and
wherein the higher permittivity dielectric columns or the lower permittivity dielectric holes are extending in a first direction, which is within +/−45° of a pushing direction.
